(19) United States
(12) Patent Application Publication
(10) Pub. No.: US 2024/0006344 A1
(43) Pub. Date: Jan. 4, 2024

(54) SEMICONDUCTOR DEVICE AND METHOD OF MANUFACTURING THE SAME

(71) Applicant: RENESAS ELECTRONICS CORPORATION, Tokyo (JP)

(72) Inventors: Yasutaka NAKASHIBA, Tokyo (JP); Toshiyuki HATA, Tokyo (JP); Hiroshi YANAGIGAWA, Tokyo (JP); Tomohisa SEKIGUCHI, Tokyo (JP)

(21) Appl. No.: 18/330,648

(22) Filed: Jun. 7, 2023

(30) Foreign Application Priority Data
Jul. 1, 2022 (JP) 2022-107032

(51) Int. Cl. H01L 23/00; H01L 23/58; H01L 29/78; H01L 21/78; H01L 21/306

(52) U.S. Cl. CPC H01L 23/562; H01L 24/32; H01L 23/585; H01L 29/7813; H01L 21/78; H01L 21/30604; H01L 2224/32225

(57) ABSTRACT

A semiconductor device includes a chip mounting portion and a semiconductor chip provided on the chip mounting portion via a conductive adhesive material. Here, a planar shape of the semiconductor chip is a quadrangular shape. Also, in plan view, a plurality of thin portions is formed at a plurality of corner portions of the semiconductor chip, respectively. Also, the plurality of thin portions respectively formed at the plurality of corner portions of the semiconductor chip is spaced apart from each other. Further, thickness of each of the plurality of thin portions is smaller than a thickness of the semiconductor chip other than the plurality of the thin portions.

### CROSS-REFERENCE TO RELATED APPLICATIONS

The disclosure of Japanese Patent Application No. 2022-107032 filed on Jul. 1, 2022, including the specification, drawings and abstract is incorporated herein by reference in its entirety.

### BACKGROUND

The present disclosure relates to a semiconductor device and a technique for manufacturing the same, and for example, to a technique that can be effectively applied to a semiconductor device including a power transistor and a technique for manufacturing the same.

Here, there are disclosed techniques listed below.

### [Patent Document 1] Japanese Unexamined Patent Application Publication No. 2016-157880

Patent Document 1 discloses a technique of forming a recess in a peripheral edge portion of a back surface of a semiconductor chip.

### SUMMARY

In a semiconductor device, a semiconductor chip is mounted, for example, on a chip mounting portion (die pad) via a conductive adhesive material. In the semiconductor device configured as described above, a temperature cycle test is performed in order to ensure a reliability of the semiconductor device. Then, when the temperature cycle test is performed, a large stress is applied to an interface between a back surface of a corner portion of the semiconductor chip and the conductive adhesive material due to the difference between a thermal expansion coefficient of the semiconductor chip and a thermal expansion coefficient of the chip mounting portion. As a result, in a semiconductor device having a low reliability, when the temperature cycle test is performed, a crack is progressed inside the conductive adhesive material from the interface between the back surface of the corner portion, to which a large stress is applied, of the semiconductor chip and the conductive adhesive material, as a starting point, thereby causing a thermal resistance defect (thermal resistance failure). For this reason, it is desired to realize a semiconductor device having a high reliability that does not cause the thermal resistance defect even when the temperature cycle test is performed.

In this regard, as a measure for reducing the stress described above, 1) a way for reducing a thickness of the semiconductor chip and 2) a way for increasing a thickness of the conductive adhesive material have been studied. However, when the thickness of the semiconductor chip is reduced, there is a concern that a crack may occur in the semiconductor chip due to a decrease in the flexural strength (bending strength) of the semiconductor chip, or a wafer crack may occur during transportation of a semiconductor wafer. On the other hand, when the thickness of the conductive adhesive material is increased, the ON-resistance of the semiconductor device is increased. Therefore, there is a demand for a way for ensuring a reliability that can withstand the temperature cycle test while achieving both of securing the flexural strength of the semiconductor chip and suppressing an increase of the ON-resistance.

A semiconductor device according to one embodiment includes a chip mounting portion and a semiconductor chip provided on the chip mounting portion via a conductive adhesive material. Here, a planar shape of the semiconductor chip is a quadrangular shape. Also, in plan view, a plurality of thin portions is formed at a plurality of corner portions of the semiconductor chip, respectively. Also, the plurality of thin portions respectively formed at the plurality of corner portions of the semiconductor chip is spaced apart from each other. Further, a thickness of each of the plurality of thin portions is smaller than a thickness of the semiconductor chip other than the plurality of the thin portions.

A method of manufacturing a semiconductor device according to one embodiment, comprising steps of: (a) forming a groove portions extending over a corner portion of each of a plurality of chip regions by partially removing a back surface of a semiconductor wafer, the semiconductor wafer having the plurality of chip regions and a scribe region located between the plurality of chip regions adjacent to each other; and (b) obtaining a semiconductor chip by cutting the semiconductor wafer along the scribe region. Here, a planar shape of the semiconductor ship obtained by the step of (b) is a quadrangular shape. Also, in plan view, a plurality of thin portions is formed at a plurality of corner portions of the semiconductor chip, respectively. Also, one of the plurality of thin portions corresponds to a part of the groove portion formed in the step of (a). Also, the plurality of thin portions respectively formed at the plurality of corner portions of the semiconductor chip is spaced apart from each other. Further, a thickness of each of the plurality of thin portions is smaller than a thickness of the semiconductor chip other than the plurality of the thin portions.

According to one embodiment, it is possible to improve the reliability of the semiconductor device.

### BRIEF DESCRIPTION OF THE DRAWINGS

FIG. 1 is a drawing schematically showing an inner structure of a semiconductor device according to an embodiment.

FIG. 2 is a plan view showing a planar layout of a semiconductor chip according to the embodiment.

FIG. 3 is a plan view of the semiconductor chip according to the embodiment having a corner portion at which a thin portion is formed.

FIG. 4 is a drawing schematically showing an example of a planar size of the thin portion according to the embodiment.

FIG. 5 is a drawing schematically showing another example of a planar size of the thin portion according to the embodiment.

FIG. 6 is a cross-sectional view of the semiconductor device corresponding to a cross section cut at A-A line in FIG.

FIG. 7 is a drawing showing a cross-sectional structure of the semiconductor chip according to the embodiment.

FIG. 8 is a drawing showing a manufacturing process of the semiconductor chip according to the embodiment.

FIG. 9 is a drawing showing a manufacturing process of the semiconductor chip following by FIG. 8.

FIG. 10 is a plan view showing a partial region of a semiconductor wafer according to the embodiment.

FIG. 11 is a drawing showing the semiconductor wafer called a 45-degree rotated substrate.

FIG. 12 is a drawing showing a manufacturing process of the semiconductor chip according to the embodiment.

FIG. 13 is a flow chart showing a flow of the manufacturing process of the semiconductor device according to the embodiment.

FIG. 14 is a plan view of a semiconductor chip according to a first modified example having a corner portion at which a thin portion is formed.

FIG. 15 is a plan view showing a partial region of a semiconductor wafer according to the first modified example.

FIG. 16 is a drawing showing the semiconductor wafer called a 0-degree rotated substrate.

FIG. 17 is a drawing showing a corner portion of a semiconductor chip according to a third modified example.

FIG. 18 is a cross-sectional view of a semiconductor device corresponding to a cross section cut at A-A line in FIG. 17.

FIG. 19 is a drawing showing a corner portion of a semiconductor chip according to a fourth modified example.

FIG. 20 is a cross-sectional view of a semiconductor device corresponding to a cross section cut at A-A line in FIG. 19.

### DETAILED DESCRIPTION

In all the drawings for explaining the embodiments, the same members are denoted by the same reference numerals in principle, and repetitive descriptions thereof are omitted. Note that even plan view may be hatched for the sake of clarity.

<Novel Finding Found by Inventor>

For example, in order to improve the reliability of the temperature cycle test, it is conceivable to reduce the thickness of the semiconductor chip. However, in this case, handling of the semiconductor wafer becomes difficult. Specifically, wafer cracking is likely to occur during transfer of the semiconductor wafer.

Therefore, a technique of forming a recessed portion over the entire peripheral portion of the semiconductor chip has been studied. According to this technique, since the thickness of the semiconductor chip can be secured except for the entire peripheral portion, while it is possible to secure the flexural strength of the semiconductor chip, in the peripheral portion, since it is possible to secure the thickness of the conductive adhesive material in contact with the semiconductor chip, it is possible to relax the stress applied to the interface between the conductive adhesive material and the back surface of the peripheral portion of the semiconductor chip. As a result, it is considered that it is possible to suppress the occurrence of a thermal resistance defect due to the occurrence of cracks in the conductive adhesive material. In other words, according to the technique of forming the recessed portion over the entire peripheral portion of the semiconductor chip, it is considered that the reliability of semiconductor device can be improved.

Further, in this technique, since the thickness of the conductive adhesive material does not increase in the region other than the peripheral portion of the semiconductor chip, an increase in the ON-resistance can be suppressed.

Therefore, according to the technique of forming the recessed portion over the entire peripheral portion of the semiconductor chip, it is considered that the reliability that can withstand the temperature cycle test can be ensured while achieving both the securing of the flexural strength of the semiconductor chip and the suppression of the increase in the ON-resistance.

However, according to studies by the present inventors, it has been found that the flexural strength of the semiconductor chip is insufficient even in a technique of forming a recessed portion over the entire peripheral portion of the semiconductor chip. That is, it has been clarified that, in the technique of forming the recessed portion over the entire peripheral portion of the semiconductor chip, it is necessary to examine the improvement from the viewpoint of ensuring the reliability that can withstand the temperature cycle test while achieving both the securing of the flexural strength of the semiconductor chip and the suppression of the increase in the ON-resistance.

In this regard, as a result of intensive studies by the present inventors, a portion where a large stress is applied in the temperature cycle test is an interface between the back surface of the corner portion of the semiconductor chip and the conductive adhesive material, starting from this interface, by cracks in the conductive adhesive material proceeds, it was found that leads to thermal resistance defect. That is, the present inventors have found that the reliability of semiconductor device can be improved by focusing on the interface between the rear surface of the corner portion of the semiconductor chip and the conductive adhesive material without paying attention to the entire peripheral portion of the semiconductor chip.

In view of the above, the present inventors have devised a technique capable of ensuring the reliability that can withstand the temperature cycle test while achieving both the securing of the flexural strength of the semiconductor chip and the suppression of the increase in the ON-resistance, based on the above-described novel findings. Hereinafter, the technical idea in the present embodiment to which the present invention is applied will be described.

<Basic Concept in Embodiment>

The basic idea in present embodiment is based on the above-described novel knowledge, focusing on the interface between the rear surface of the corner portion of the semiconductor chip and the conductive adhesive material, a thin portion is provided at each corner portion of the semiconductor chip having a rectangular planar shape, the thin portion formed at each corner portion of the semiconductor chip is separated from each other, the thickness of the thin portion formed at each corner portion of the semiconductor chip is thinner than the thickness of the semiconductor chip other than the thin portion.

Accordingly, since the thin portion is formed at each corner portion of the semiconductor chip, the thickness of the conductive adhesive material in contact with the thin portion can be increased. This means that the stress can be relaxed at each corner portion, whereby the conductive adhesive material is cracked and progresses, thereby suppressing the thermal resistance defect.

In particular, according to the novel findings found by the present inventors, a portion where a large stress is applied in the temperature cycle test is an interface between the back surface of each corner portion of the semiconductor chip and the conductive adhesive material, in the basic idea, the thin portion is formed at each corner portion to which a large stress is applied. Thus, according to the basic idea, it is possible to realize stress-relaxation at the respective corner portions, and thus it is possible to improve the reliability of semiconductor device.

In the basic concept, thin portions formed at respective corners of the semiconductor chip are separated from each other. In other words, in the basic concept, the thin portion is not provided over the entire peripheral portion of the semiconductor chip. As a result, since a region having a small thickness does not exist in the semiconductor chip over the entire peripheral portion of the semiconductor chip, the flexural strength of the semiconductor chip can be improved. Therefore, according to the basic idea, it is possible to suppress the wafer cracking at the time of transporting the semiconductor wafer, and as a result, it is possible to obtain the advantage that the handling of the semiconductor wafer is facilitated.

Further, in the basic idea, the thickness of the conductive adhesive material is increased only at a portion of the conductive adhesive material that is in contact with the thin portion, while the thickness of the conductive adhesive material is not increased at another portion, so that an increase in the ON-resistance of semiconductor device can be suppressed.

As described above, according to the basic concept, it is possible to secure the reliability that can withstand the temperature cycle test while achieving both the securing of the flexural strength of the semiconductor chip and the suppression of the increase in the ON-resistance.

Therefore, the basic idea conceived based on the novel findings found by the present inventors can be said to be a very excellent technical idea in that it is possible to secure the reliability that can withstand the temperature cycle test without sacrificing the flexural strength and the ON-resistance of the semiconductor chip by the minimum necessary idea that the thin portions provided at each corner portion are separated from each other.

In the following, embodiments embodying this basic idea will be described.

### Embodiment

<<Packaging Configuration of Semiconductor Device>>

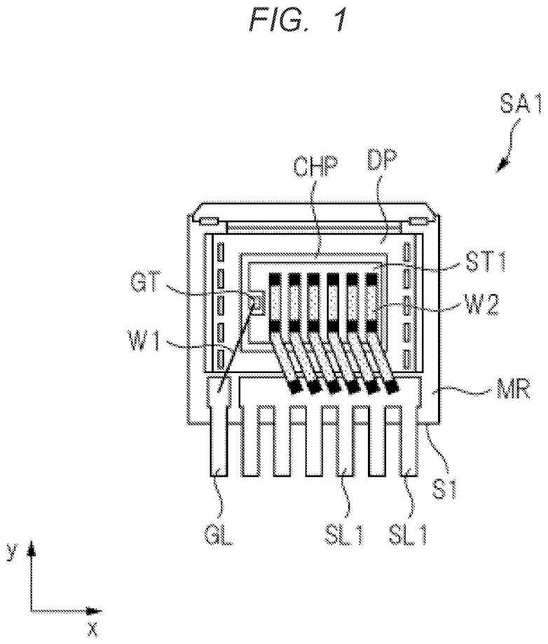

FIG. 1 is a drawing schematically showing an inner structure of a semiconductor device SA1.

In FIG. 1, for example, a die pad DP is disposed inside a sealing body MR. A semiconductor chip CHP is mounted on the die pad DP. A power MOSFET (Metal Oxide Semiconductor Field Effect Transistor) is formed on the semiconductor chip CHP.

The surface chip CHP includes a semiconductor chip MOSFET having a gate pad GT electrically connected to a gate electrode of the semiconductor chip and a source pad ST1 electrically connected to a source area of the power MOSFET.

On the other hand, although not shown in FIG. 1, a drain electrode (drain terminal) of the power MOSFET is formed on the back surface of the semiconductor chip CHP, and the drain electrode is electrically connected to the die pad DP.

Next, a plurality of leads is arranged so as to protrude from the sealing body MR on the side S1 of the sealing body MR. Specifically, the plurality of leads includes a gate pad lead GL and a source pad lead SL1.

The gate pad lead GL is electrically connected to the gate pad GT via a wire W1 which is a gate pad connecting member. The lead SL1 for the source pad is electrically connected to the source pad ST1 by a plurality of wire W2 that is connecting members for the source pad.

For example, the wire W1 is a gold or copper-based wire, while the wire W2 is an aluminum-based wire.

Here, the term “main component” refers to the most abundant component, and is used to indicate that the inclusion of other components is not excluded. For example, “based on gold” means that it contains the most gold, and similarly, “based on aluminum” means that it contains the most aluminum.

In this way, semiconductor device SA1 that is the “TO packaging” is configured.

In present embodiment, for example, as shown in FIG. 1, “TO (Transistor Outline) package” is adopted as a package structure of a semiconductor device SA1 having a semiconductor chip on which a power MOSFET is formed. Here, “TO package” is defined as a package structure in which a plurality of leads is arranged only on the first side S1 of semiconductor device in a plan view. In this regard, “TO package” differs from “SON (Small Outline Non-Leaded) package” and “SOP (Small Outline Package) package”, in which not only the first side S1 of semiconductor device but also a plurality of leads are arranged on the second side opposite to the first side S1, and further differs from “QFN (Quad Flat Non-leaded) package” and “QFP (Quad Flat Package) package”, in which a plurality of leads are arranged on all four sides of semiconductor device. According to “TO package” adopted in present embodiment, for example, since a plurality of leads are arranged only on the first side S1 of semiconductor device SA1, the wiring on the motherboard can be easily routed as compared with the other packages described above. For example, by adopting “TO packaging”, it is possible to realize a mounting layout corresponding to an inverter-circuit with a simplified layout. Note that, although FIG. 1 illustrates a W2 of a semiconductor device SA1 having a plurality of wires, for example, the lead SL1 for a source pad and the source pad ST1 may be electrically connected by one thick wire, or may be electrically connected by using clips (plate-shaped members) or ribbons.

In FIG. 1, a power MOSFET is exemplified as a power transistor formed on a semiconductor chip CHP, but for example, not only a power MOSFET but also a IGBT (Insulated Gate Bipolar Transistor can be used as a power transistor. Here, the source region of the power MOSFET corresponds to the emitter region of IGBT, while the drain electrode of the power MOSFET corresponds to the collector electrode of IGBT. The source pad ST1 shown in FIG. 1 is, for example, an emitter pad.

<Layout of Semiconductor Chip>

Next, a planar layout of the semiconductor chip CHP will be described.

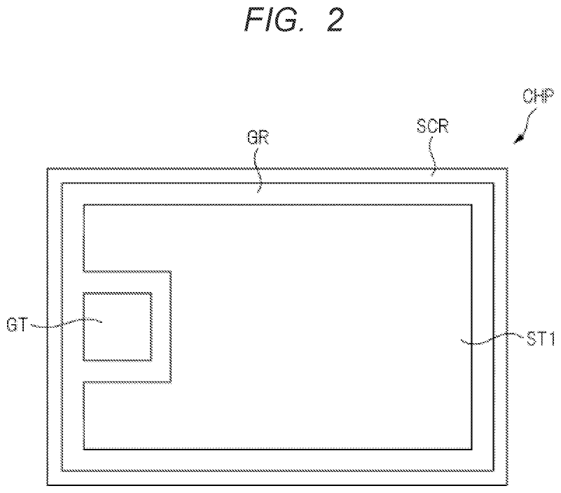

FIG. 2 is a plan view showing the planar layout of the semiconductor chip CHP.

In FIG. 2, the planar shape of the semiconductor chip CHP is a quadrangular shape, and the source pad ST1 and the gate pad GT are formed on the active region. Here, the “active region” is defined as a region in which a power MOSFET is formed. The source pad ST1 is electrically connected to the source area of the power MOSFET, while the gate pad GT is electrically connected to the gate electrode of the power MOSFET.

Next, the semiconductor chip CHP includes a guard ring region GR that planarly surrounds the active region in which the power MOSFET is formed, and a scribe region SCR that planarly surrounds the guard ring region GR. The “guard ring region” is an outer region of the active region, and a high breakdown voltage structure represented by a field limited ring (FLR) is formed in the guard ring region. As a result, the withstand voltage of the guard ring region becomes higher than that of the active region, so that the withstand voltage of semiconductor device SA1 is controlled by the withstand voltage of the active region instead of the withstand voltage of the guard ring region. In other words, the breakdown voltage of semiconductor device SA1 can be made equal to the breakdown voltage of the active region by forming the breakdown voltage in the guard ring region.

The “scribe region” is defined as a margin region of the dicing line when the chip region of the semiconductor wafer is diced to obtain the semiconductor chip CHP. That is, the “scribe region” is a dicing region including a dicing line.

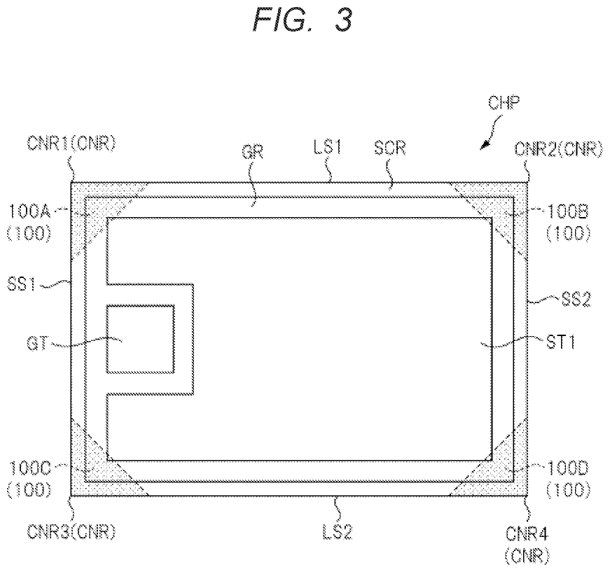

FIG. 3 is a plan view of the semiconductor chip having a corner portion at which a thin portion is formed.

In FIG. 3, the semiconductor chip CHP has a corner portion CNR1, a corner portion CNR2, a corner portion CNR3 and a corner portion CNR4 that are four corner portions. A thin portion 100A is formed at the corner portion CNR1, and a thin portion 100B is formed at the corner portion CNR2. Further, a thin portion 100C is formed at the corner portion CNR3, and a thin portion 100D is formed at the corner portion CNR4. At this time, for example, the planar shape of each of the thin portion 100A, the thin portion 100B, the thin portion 100C and the thin portion 100D is composed of a triangular shape.

For example, it is assumed that the planar shape of the thin portion 100A is composed of the first triangular shape, the planar shape of the thin portion 100B is composed of the second triangular shape, the planar shape of the thin portion 100C is composed of the third triangular shape, and the planar shape of the thin portion 100D is composed of the fourth triangular shape.

In this case, the desired first triangular shape, the second triangular shape, the third triangular shape, and the fourth triangular shape are a planar shape shown below. That is, the length of the side, which is overlapping with the side LS1 of the semiconductor chip CHP, among the three sides composing the first triangular shape is less than or equal to a quarter of the length of the side LS1, and the length of the side, which is overlapping the side LS1 of the semiconductor chip, among the three sides composing the second triangular shape is less than or equal to a quarter of the length of the side LS1. Further, the length of the side, which is overlapping the side SS1 of the semiconductor chip CHP, among the three sides composing the first triangular shape is less than or equal to a quarter of the length of the side SS1, the length of the side, which is overlapping the side SS2 of the semiconductor chip, among the three sides composing the second triangular shape is less than or equal to a quarter of the length of the side SS2.

Similarly, the length of the side, which is overlapping the side LS2 of the semiconductor chip CHP, among the three sides composing the third triangular shape is less than or equal to a quarter of the length of the side LS2, and the length of the side, which is overlapping the side LS2 of the semiconductor chip, among the three sides composing the fourth triangular shape is less than or equal to a quarter of the length of the side LS2. Further, the length of the side, which is overlapping the side SS1 of the semiconductor chip CHP, among the three sides composing the third triangular shape is less than or equal to a quarter of the length of the side SS1, the length of the side, which is overlapping the side SS2 of the semiconductor chip, among the three sides composing the fourth triangular shape is less than or equal to a quarter of the length of the side SS2. As a result, the above-described basic idea can be realized, and the reliability that can withstand the temperature cycle test can be ensured while achieving both the securing of the flexural strength of the semiconductor chip CHP and the suppressing of the increase in the ON-resistance.

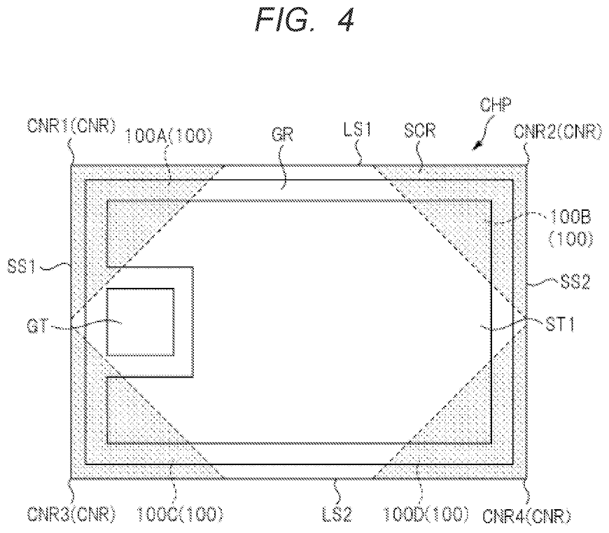

However, the thin portion 100A, the thin portion 100B, the planar size of the thin portion 100C and the thin portion 100D may be larger than the planar size described above. Specifically, FIG. 4 is a drawing schematically showing an example of a planar size of each of a thin portion 100A, a thin portion 100B, the thin portion 100C and the thin portion 100D. As shown in FIG. 4, for example, when attention is paid to the corner portion CNR1 provided at one end portion (left end portion) of the side LS1 of the semiconductor chip CHR and the corner portion CNR2 provided at other end portion (right end portion) of the side LS1 of the semiconductor chip CHP, the thin portion 100A formed at the corner portion CNR1 and the thin portion 100B formed at the corner portion CNR2 are not contacted with each other.

Similarly, the thin portion CHP formed on the edge SS1 of the semiconductor chip CNR1 (upper end portion) and the other end portion (lower end portion) of the side CHP of the semiconductor chip SS1 are not contacted with each other when attention is paid to the corner portion CNR3 provided on the other end portion (lower end portion) of SS1 of the side, the thin portion 100A formed on the corner portion CNR1 and the corner portion CNR3. That is, as shown in FIG. 4, the adjacent thin portions 100 to each other among the thin portions 100 respectively formed at the corner portions CNR of the semiconductor chip CHP are separated from each other so as not to be contacted with each other. In other words, the thin portion 100 is not provided between the two thin portions 100 adjacent to each other.

In this case, the thin portion 100A shown in FIG. 4, the thin portion 100B, the flat size of the thin portion 100C and the thin portion 100D, the thin portion 100A shown in FIG. 3, the thin portion 100B, the thin portion 100C and because it is larger than the planar size of the thin portion 100D, while leading to an increase in the allowable range of lowering and ON-resistance within the allowable range of the transverse rupture strength of the semiconductor chip CHP, it is possible to further improve the reliability that can withstand the temperature cycle test. This is because it is possible to increase the planar sizes of thin 100A, thin 100B, thin 100C and thin 100D that can mitigate the stresses.

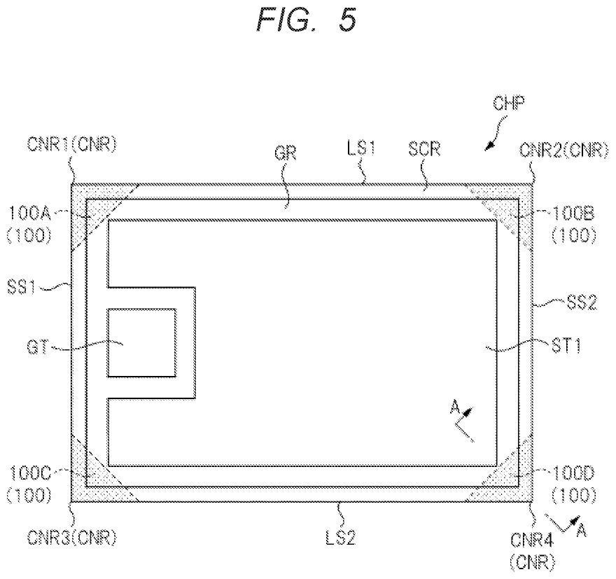

In contrast, FIG. 5 is a drawing schematically showing another example of a planar size of each of the thin portion 100A, the thin portion 100B, the thin portion 100C and the thin portion 100D. As shown in FIG. 5, each of the thin portion 100A, the thin portion 100B, the thin portion 100C and the thin portion 100D is composed to have a region overlapping at least the scribe region SCR and the guard ring region GR. As a result, it is possible to secure the reliability that can withstand the temperature cycle test while achieving both the securing of the flexural strength of the semiconductor chip CHP and the suppressing of the increase in the ON-resistance.

In particular, by approaching the planar size of each of the thin portion 100A, the thin portion 100B, the thin portion 100C and the thin portion 100D to the planar size shown in FIG. 5, it is possible to effectively realize to secure the flexural strength of the semiconductor chip CHP and to suppress an increase of the ON-resistance of the semiconductor chip CHP. However, as the planar size of each of the thin portion 100A, the thin portion 100B, the thin portion 100C and the thin portion 100D is closer to the planar size shown in FIG. 5, the planar size of each of the thin portion 100A, the thin portion 100B, the thin portion 100C and the thin portion 100D that can relax the stress is reduced. Therefore, the reliability that can withstand the temperature cycle test tends to decrease within the allowable range. Then, the planar size of each of the thin portion 100A, the thin portion 100B, the thin portion 100C and the thin portion 100D is to be more reduced than the planar size shown in FIG. 5 so as not to overlap the guard ring region GR, then it is difficult to ensure reliability that can withstand the temperature cycle test.

From the above, by embodying the basic concept, while achieving both the security of the flexural strength of the semiconductor chip CHP and suppression of the increase in the ON-resistance, from the viewpoint of ensuring the reliability that can withstand the temperature cycle test, it is desirable that the planar size of each of the thin portion 100A, the thin portion 100B, the thin portion 100C and the thin portion 100D is, as shown in FIG. 5, at least, equal to or more than the planar size including a region that overlaps the scribe region SCR and the guard ring region GR. Also, it is desirable that the planar size of each of the thin portion 100A, the thin portion 100B, the thin portion 100C and the thin portion 100D is, as shown in FIG. 4, equal to or less than the planar size that the adjacent thin portions 100 to each other among the thin portions 100 respectively formed at the corner portions CNR of the semiconductor chip CHP are spaced apart from each other so as not to be contacted with each other.

<<Cross-Sectional Structure of Semiconductor Device>>

Next, a cross-sectional structure of the semiconductor device SA1 will be described.

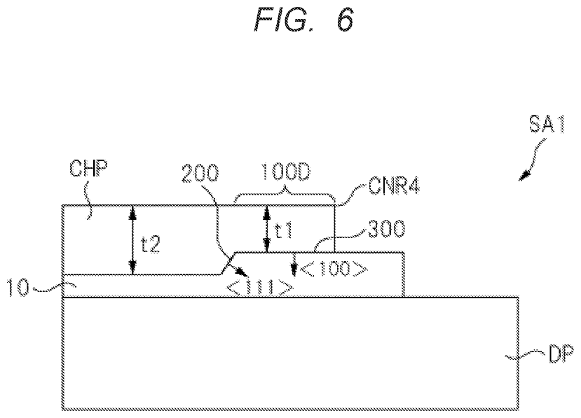

FIG. 6 is a cross-sectional view of the semiconductor device SA1 corresponding to a cross-section cut at A-A line of FIG. 5.

As shown in FIG. 6, a semiconductor chip CHP is mounted on a die pad (chip mounting portion) DP via a conductive adhesive material 10 made of, for example, solder. Here, a thin portion 100D is formed at a corner portion CNR4 of the semiconductor chip CHP. The thickness 100D of the thin portion t1 is thinner than the thickness t2 other than the thin portion 100D. Consequently, the thickness of the conductive adhesive material 10 in contact with the thin portion 100D is larger than the thickness of the conductive adhesive material 10 in contact with regions other than the thin portion 100D.

Accordingly, in the temperature cycle test, since the stresses applied to the corner portions CNR4 are relaxed by the conductive adhesive material 10 having a large thickness, it is possible to prevent the conductive adhesive material 10 from cracking and progressing, resulting in the thermal resistance defect.

In FIG. 6, the thin portion 100D includes an inclined portion 200 connected to the back surface of the semiconductor chip CHP and a flat portion 300 connected to the inclined portion 200. In particular, in an implementation, the semiconductor chip CHP is a silicon chip, the normal direction of the ramp 200 is the <111> direction, and the normal direction of the flat portion 300 is the <100> direction.

Here, in an implementation, a semiconductor chip obtained from a semiconductor wafer called a 45-degree rotated substrate is used. The 45-degree rotated substrate means a silicon substrate in which the crystal axis (the thickness direction of the semiconductor chip CHP) is in the <100> direction and the plane orientation of the orientation flat is in the {100} plane, or a silicon substrate in which the crystal axis is in the <100> direction and the normal direction of the notches is in the <100> direction.

In this regard, in the semiconductor chip CHP acquired from the 45-degree rotated substrate, considering that the vertical typed trench power MOSFET is formed in the semiconductor chip CHP, the channel plane, which is the plane through which the current of the vertical typed trench power MOSFET flows, is the {100} plane. In view of the fact that the {100} plane is a plane having a higher carrier mobility, this means that the ON-resistance of the power MOSFET formed on the semiconductor chip CHP can be reduced according to the embodiment.

In particular, referring to FIG. 6, the ON-resistance of the power MOSFET formed on CHP can be reduced according to the embodiment by the synergistic effect of the ON-resistance reduction factor caused by the point that the thickness of the conductive adhesive material 10 in contact with the region other than the thin portion 100D can be reduced, and the ON-resistance reduction factor caused by the formation of the thin portion 100D such that the channel plane of the vertical typed trench power MOSFET is the {100} plane having a high carrier mobility.

<<Cross-Sectional Structure of Semiconductor Chip>>

Next, a cross-sectional structure of the semiconductor chip CHP will be described.

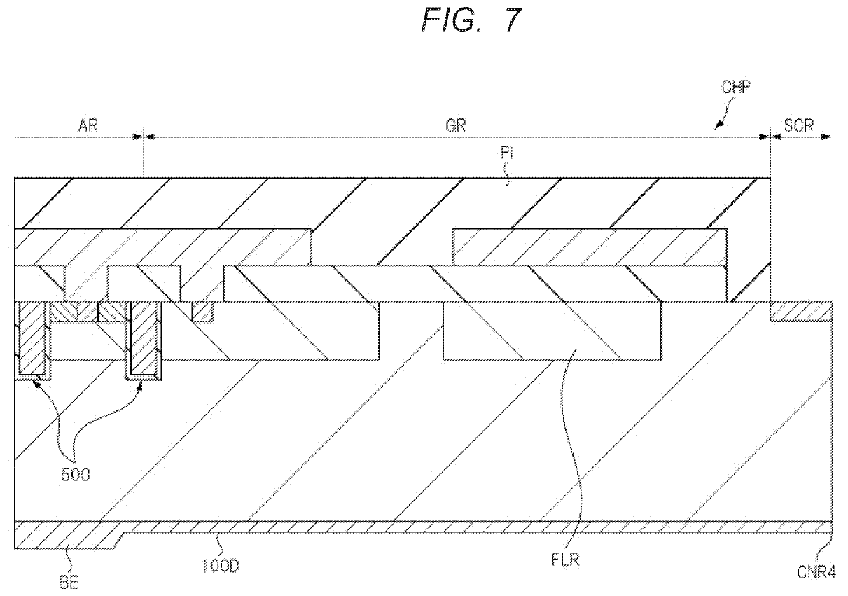

FIG. 7 is a drawing showing a cross-sectional structure of the semiconductor chip CHP.

In FIG. 7, the semiconductor chip CHP includes an active region AR in which a power MOSFET 500 is formed, a guard ring region GR provided in an outer region of the active region AR, and a scribe region SCR provided in an outer region of the guard ring region GR.

The semiconductor chip CHP has a front surface and a back surface, and a back surface electrode BE functioning as a drain electrode is formed on the back surface of the semiconductor chip CHP. On the other hand, a polyimide-resin film PI is formed on the semiconductor chip CHP. However, in the scribe region SCR, the polyimide resin film PI is removed.

In the active region AR, for example, the vertical typed trench power MOSFET is formed as an example of the power MOSFET 500. On the other hand, in the guard ring region GR, a field-limited ring FLR for making the breakdown voltage of the guard ring region GR higher than the breakdown voltage of the active region AR is formed.

Here, a thin portion 100D is formed from the guard ring region GR to the scribe region SCR. The thin portion 100D is formed by reducing the film thickness of the back surface electrode BE. That is, the back surface electrode BE is also provided at the thin portion 100D. In other words, in the thin portion 100D, the back surface electrode BE is not completely removed. In this manner, the thin portion 100D is formed at the corner portion CNR4 of the semiconductor chip CHP.

<<Method of Manufacturing Semiconductor Chip>>

Next, a method of manufacturing the semiconductor chip CHP will be described.

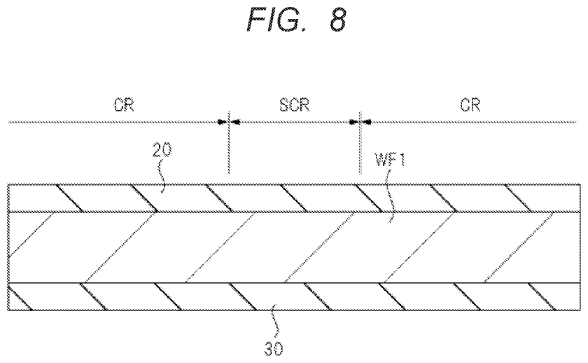

First, in FIG. 8, a power MOSFET is formed on a semiconductor wafer WF1 by using a conventional semiconductor manufacturing technique. Specifically, the semiconductor wafer WF1 has a plurality of chip regions CR, and a power MOSFET is formed in each of the plurality of chip regions CR. Here, as shown in FIG. 8, scribe regions SCR are formed between the chip regions CR adjacent to each other. The chip regions CR includes the active region AR and the guard ring region GR shown in FIG. 7. Then, as shown in FIG. 8, the front surface protective film 20 is formed on the front surface of the semiconductor wafer WF1, and an insulating film 30 typified by a silicon oxide film is formed on the back surface of the semiconductor wafer WF1.

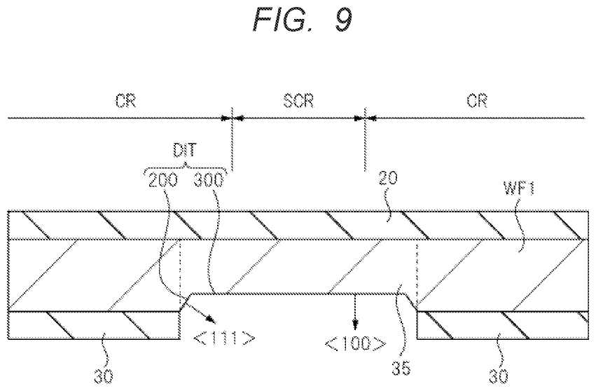

Next, as shown in FIG. 9, the insulating film 30 formed on the back surface of the wafer WF1 is patterned by using, for example, a photolithography technique and an etching technique. The insulating film 30 is patterned so that the insulating film 30 does not remain in the regions where the groove DIT is formed. Thereafter, as shown in FIG. 9, the groove DIT is formed on the back surface (the surface exposed from the insulating film 30) of the semiconductor wafer WF1 by wet etching using the patterned insulating film 30 as a mask. That is, by partially removing the back surface of the semiconductor wafer having the plurality of chip regions CR and the scribe regions SCR between the chip regions CR adjacent to each other, the groove portion DIT extending over the respective corners of the plurality of chip regions CR is formed.

Specifically, the wet etching is performed using tetramethylammonium hydroxide (TMAH: Tetramethylammonium hydroxide). At this time, since the wet etching tends to proceed in the <100> direction of the silicon, while it is difficult to proceed in the <111> direction of the silicon, the groove DIT formed by the wet etching has an inclined portion 200 having a <111> direction as a normal direction and a flat portion 300 having a <100> direction as a normal direction.

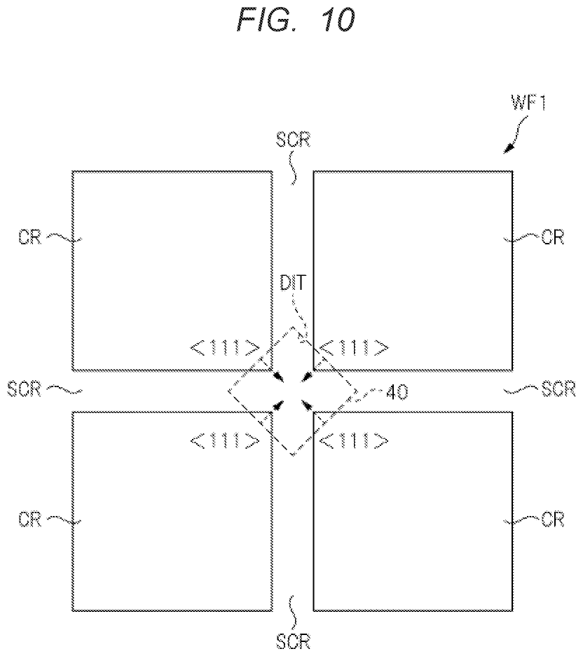

FIG. 10 is a plan view showing a partial region of a semiconductor wafer WF1, and the four chip regions CR partitioned by a scribe regions SCR are shown in FIG. 10. In FIG. 10, the processing region 40 indicated by the broken line region is a region to be wet etching by TMAH. This processing region 40 is realized by using a 45-degree rotated substrate as the semiconductor wafer WF1. The processing region 40 extends over a corner portion of each of the plurality of chip regions CR. As a result, when the inside of the processing region 40 is wet-etched, the groove DIT is formed which extends over the corner portions in the plurality of chip regions CR.

Here, the 45-degree rotated substrate (silicone substrate) will be described.

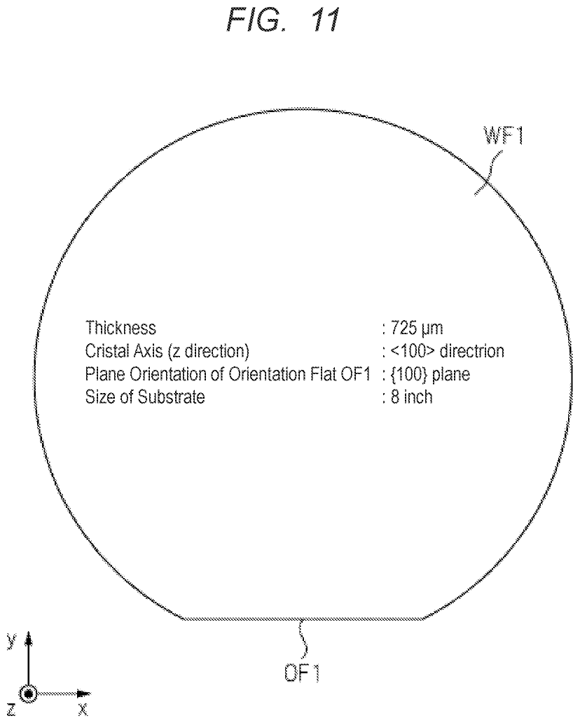

FIG. 11 a drawing showing the semiconductor wafer WF1 called the 45-degree rotated substrate. In FIG. 11, the semiconductor wafer WF1 that is the 45-degree rotated substrate is composed of a stacked structure of a semiconductor substrate and an epitaxial layer, and has a thickness of, for example, 725 micrometers. Also, the crystal axis (z direction) is the <100> direction, and the plane orientation of the orientation flat OF1 is the {100} plane. Also, the size of the substrate is 8 inch. Such a semiconductor wafer WF1 is the 45-degree rotated substrate.

When a notch is formed on the semiconductor wafer WF1 instead of the orientation flat OF1, the 45-degree rotated substrate is a silicon substrate in which the crystal axis is in the <100> direction and the normal direction (notch symmetric axis direction) of the notch is in the <100> direction.

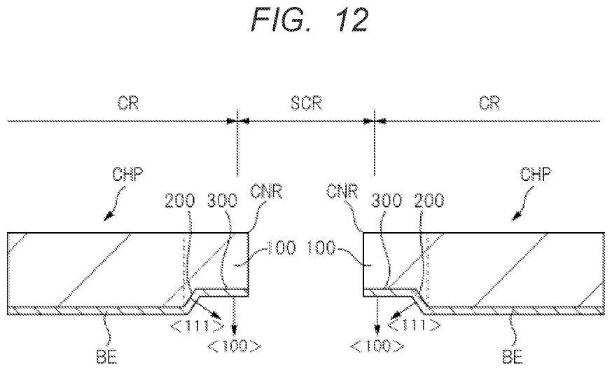

Subsequently, the semiconductor chip CHP as shown in FIG. 12 is obtained by cutting a plurality of chip regions CR including the groove DIT along the scribe regions SCR in FIG. after the back surface electrode BE is formed on the back surface of the semiconductor wafer WF1 in which the groove DIT is formed.

The planar shape of the obtained semiconductor chip CHP is a quadrangular shape, and a plurality of thin portions 100 is formed at respective corner portions of the semiconductor chip CHP in a plan view. One of the plurality of thin portions 100 corresponds to a part (see FIGS. 9 and 12) of the portion 35, at where the groove portion DIT shown in FIG. 9 is formed, of the semiconductor wafer WF1. The thin portions 100 formed at the respective corner portions of the semiconductor chip CHP are spaced apart from each other, and the thickness of each of the plurality of thin portions 100 respectively formed at the corner portions of the semiconductor chip CHP is smaller than the thickness of the semiconductor chip CHP other than the plurality of thin portions 100.

Here, each of the plurality of thin portions 100 respectively formed at the plurality of corner portions CNR includes an inclined portion 200 having a <111> direction as a normal direction, and a flat portion 300 having a <100> direction as a normal direction. When the 45-degree rotated substrate is used, the planar shape of each of the plurality of thin portions 100 is a triangular shape. As described above, the semiconductor chip CHP according to the embodiment can be manufactured.

<<Method of Manufacturing Semiconductor Device>>

Next, a method of manufacturing the semiconductor device will be described.

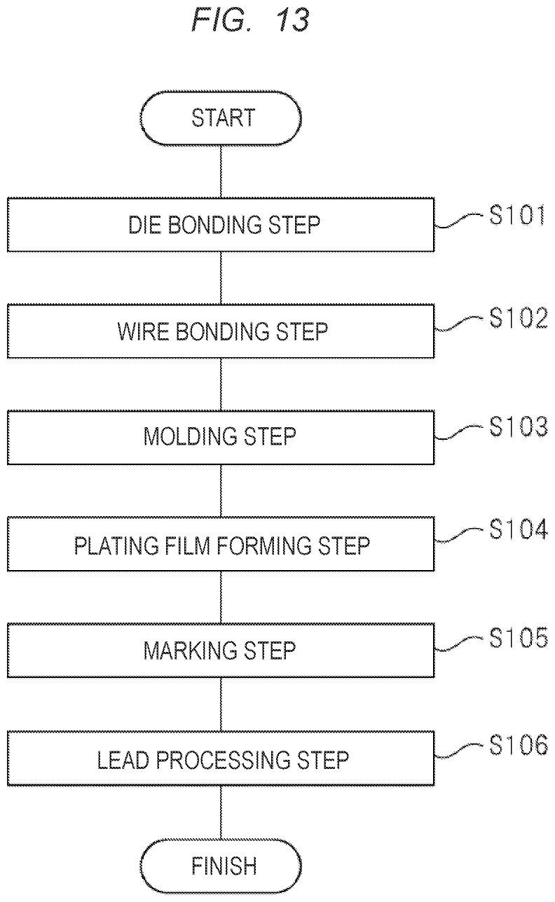

FIG. 13 is a flow chart showing a flow of the manufacturing process of the semiconductor device.

A semiconductor chip obtained by dicing the semiconductor wafer WF1 as shown in FIG. 12 is die-bonded onto a die pad (S101). Specifically, the semiconductor chip is mounted on a die pad (chip mounting portion) formed in a lead frame via a conductive adhesive material typified by a solder. Specifically, the semiconductor chip is mounted on the die pad via the conductive adhesive material so that the conductive adhesive material is in contact not only with the back surface of the semiconductor chip but also with the thin portion formed at the corner portion of the semiconductor chip. Thus, the thickness of the conductive adhesive material in contact with the thin portion is greater than the thickness of the conductive adhesive material in contact with the back surface other than the thin portion.

Next, the source pad formed on the surface of the semiconductor chip and the lead for the source pad provided on the lead frame are electrically connected by a wire, and the gate pad formed on the surface of the semiconductor chip and the lead for the gate pad provided on the lead frame are electrically connected by a wire (S102). Here, the diameter of the wire connecting the source pad and the lead for the source pad is large, and the wire is made of, for example, aluminum. On the other hand, the diameter of the wire connecting the gate pad and the gate pad lead is smaller than the diameter of the wire connecting the source pad and the source pad lead, and is made of, for example, aluminum. However, the wire connecting the gate pad and the gate pad lead may be made of gold.

Subsequently, upper surface of the die pad, the conductive adhesive material, the semiconductor chip, the plurality of wires, and the inner lead portion of the lead are resin-sealed to form a sealing body (S103). Note that, for example, the lower surface of the die pad may be formed so as to be covered with the sealing body, or may be exposed from the sealing body in consideration of heat dissipation. An example of the resin composing the sealing body includes a thermosetting resin typified by an epoxy resin.

Then, after a plating film is formed on the outer lead portion of the lead exposed from the sealing body (S104), a marking step is performed (S105). In the marking step, for example, a desired mark is formed on the surface of the sealing body. The mark indicates a type, a model number, or the like of the product, and is formed by irradiating the surface of the sealing body with a laser.

Thereafter, the outer lead portion of the lead provided in the lead frame is cut, and the cut outer lead is further processed into, for example, a gull-wing shape (S106).

As described above, semiconductor device in the embodiment can be manufactured.

### Features in Embodiment

Subsequently, a description will be given of the features in the embodied embodiment.

The first characteristic point in the embodiment is, for example, as shown in FIG. 3, in that the thin portion 100 is provided on each corner portion CNR of the semiconductor chip CHP having a rectangular planar shape, the thin portion 100 formed on each corner portion CNR of the semiconductor chip CHP is separated from each other, and the thickness of the thin portion 100 formed on each corner portion CNR of the semiconductor chip CHP is made thinner than the thickness of the semiconductor chip CHP other than the thin portion 100. Specifically, the first characteristic point is that the thin portion 100A is provided in the corner portion CNR1, and the thin portion 100B is provided in the corner portion CNR2, and the thin portion 100A is provided in the corner portion CNR3, and the thin portion 100C is provided in the corner portion 100B, and the thin portion 100D is provided in the corner portion CNR4, while the thin portion 100A, the thin portion 100C, and the thin portion 100D are spaced from each other, the thin portion 100A, the thin portion 100C, and the thickness of the thin portion 100D is in a point that is thinner than the thickness of the semiconductor chip CHP other than the thin portion 100. Thus, according to the first aspect, without providing a thin portion over the entire peripheral portion of the semiconductor chip CHP, the thin portion 100 provided on each corner portion CNR by the minimum idea of being separated from each other, without sacrificing the flexural strength and the ON-resistance of the semiconductor chip CHP, it is possible to secure the reliability that can withstand the temperature cycle test.

For example, in a configuration in which a thin portion is provided over the entire peripheral portion of the semiconductor chip CHP, it is possible to ensure reliability that can withstand the temperature cycle test, while it is difficult to secure the flexural strength of the semiconductor chip CHP.

In this regard, a portion to which large stresses are applied in the temperature cycle test is an interface between the rear surface of the corner portion CNR of the semiconductor chip CHP and the conductive adhesive material, and the conductive adhesive material is cracked and progresses starting from this interface, leading to the thermal resistance defect. That is, the present inventor has obtained as a novel finding that the reliability of semiconductor device can be improved by focusing on the interface between the rear surface of the corner portion CNR of the semiconductor chip CHP and the conductive adhesive material without paying attention to the entire peripheral portion of the semiconductor chip CHP. Then, the new knowledge is motivated, the first feature that the thin portions 100 respectively provided at the corner portions CNR are separated from each other has been conceived, according to the first feature, while it is possible to secure the reliability that can withstand the temperature cycle test in a required sufficient area, since the thin portion 100 is not formed in the region other than the region forming the thin portion 100, it is possible to improve the flexural strength of the semiconductor chip CHP. That is, according to the first aspect, it is possible to secure the flexural strength of the semiconductor chip CHP while ensuring the reliability that can withstand the temperature cycle test.

Next, a second characteristic point in the embodiment is that, on the premise that the first characteristic point described above, the allowable area of the flat surface of the thin portion 100 provided on the corner portion CNR is quantitatively defined. Specifically, as an allowable example of the planar size of the thin portion 100, for example, as shown in FIG. 4, a thin portion (e.g., a thin portion 100A) provided at one end portion (e.g., a corner portion CNR1) of one side (e.g., a side LS1) of the semiconductor chip CHP and a thin portion (e.g., a thin portion 100B) provided at the other end portion of the one side (e.g., a corner portion CNR2) present at the other end portion of the one side are separated from each other so as not to be contacted with each other. Thus, it is possible to differentiate from the configuration in which the thin portion 100 is formed over the entire peripheral portion of the semiconductor chip CHP, whereby the flexural strength of the semiconductor chip CHP can be made larger than the flexural strength of the semiconductor chip CHP in a configuration in which the thin portion 100 is formed over the entire peripheral portion.

Further, in the second characteristic point, as an allowable example of the planar size of the thin portion, for example, as shown in FIG. 5, it is defined that the thin portion 100 is configured to have at least a region that overlaps with the scribe region SCR and the guard ring region GR in a planar manner. As a result, it is possible to clearly define the minimum allowable range in which the reliability that can withstand the temperature cycle test can be ensured. That is, when the planar size of the thin portion is less than the minimum allowable range, it is difficult to ensure the reliability that can withstand the temperature cycle test. As described above, the second characteristic point has a great significance in that it is possible to clearly differentiate the configuration in which the thin portion 100 is provided over the entire peripheral portion of the semiconductor chip CHP, while securing the flexural strength of the semiconductor chip CHP, and it clearly indicates a sufficient area in which the reliability that can withstand the temperature cycle test can be secured.

Subsequently, the third feature point in the embodiment is, for example, that the thin portion is composed of an inclined portion having a <111> direction as a normal direction and a flat portion having a <100> direction as a normal direction. Thus, according to the third characteristic point, by successfully utilizing the direction in which etching by wet etching by TMAH is difficult to proceed (<111> direction) and the direction in which etching is easy to proceed (<100> direction), it is possible to cleanly process the thin portion.

Further, according to the third aspect, since the channel plane of the vertical typed trench power MOSFET formed in the semiconductor chip CHP is a {100} plane having a high carrier mobility, the ON-resistance of the vertical typed trench power MOSFET through which a current flows in the thickness direction can be reduced. Further, according to the first feature that the thin portions 100 provided in the respective corner portions CNR are separated from each other, the thickness of the conductive adhesive material in contact with the thin portions 100 is increased, but the thickness of the conductive adhesive material in contact with the other regions can be decreased, so that the ON-resistance of the vertical typed trench power MOSFET can be reduced. In other words, according to the embodiment, it is possible to reduce the ON-resistance of the vertical typed trench power MOSFET formed in CHP of the semiconductor chip by the synergistic factor of the first feature point and the third feature point.

From the above, according to the combination of the first feature point, the second feature point, and the third feature point in the embodiment, it is possible to secure the reliability that can withstand the temperature cycle test while achieving both the securing of the flexural strength of the semiconductor chip CHP and the suppressing of the increase in the ON-resistance. In other words, according to the embodiment, it is possible to secure the reliability that can withstand the temperature cycle test without sacrificing the flexural strength and the ON-resistance of the semiconductor chip CHP.

### First Modified Example

Next, a first modified example will be described.

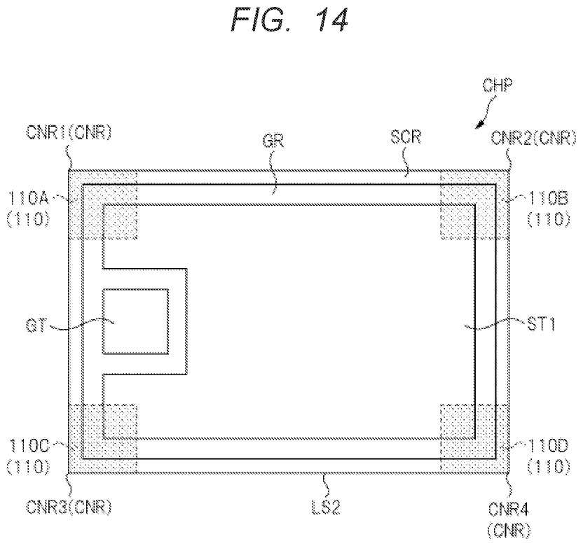

FIG. 14 is a plan view of a semiconductor chip having a corner portion at which a thin portion is formed.

In FIG. 14, the semiconductor chip CHP has a corner portion CNR1, a corner portion CNR2, a corner portion CNR3 and a corner portion CNR4 that are four corner portions. A thin portion 110A is formed at the corner portion CNR1, and a thin portion 110B is formed at the corner portion CNR2. Further, a thin portion 110C is formed at the corner portion CNR3, and a thin portion 110D is formed at the corner portion CNR4. At this time, in the present first modified example, a semiconductor wafer WF2 called a 0-degree rotated substrate is used. Thus, in the embodied embodiment, whereas the planar shape of the thin portion 100 was a triangular shape, in the present first modified example, for example, the thin portion 110A, the thin portion 110B, the planar shape of the thin portion 110C and the thin portion 110D is composed of a square shape.

Thus, the thin portion 110A, the thin portion 110B, the planar shape of the thin portion 110C and the thin portion 110D may be composed of a square shape.

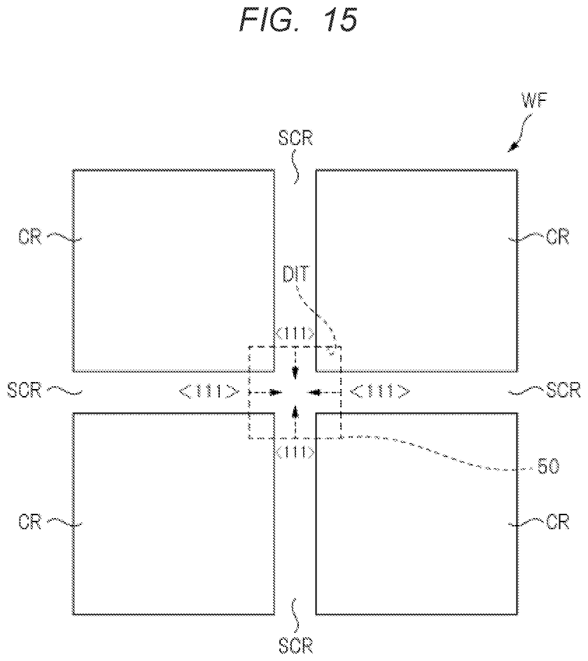

FIG. 15 is a plan view showing a partial region of a semiconductor wafer WF2, and four chip regions CR partitioned by a scribe region SCR is shown in FIG. 15. In FIG. 15, the processing region 50 indicated by the broken line region is a region to be wet etching by TMAH. The processing region 50 extends over a corner portion of each of the plurality of chip regions CR. As a result, when the inside of the processing region 50 is wet-etched, a groove DIT is formed which straddles the corner portions in the plurality of chip regions CR. Then, the inside of the processing region 50 is wet-etched, and then diced along the scribe region SCR. As a result, as shown in FIG. 14, the semiconductor chip CHP in which the thin portion 110 having a rectangular planar shape is formed on the corner portion CNR can be obtained.

Here, a 0-degree rotated substrate (silicone substrate) will be described.

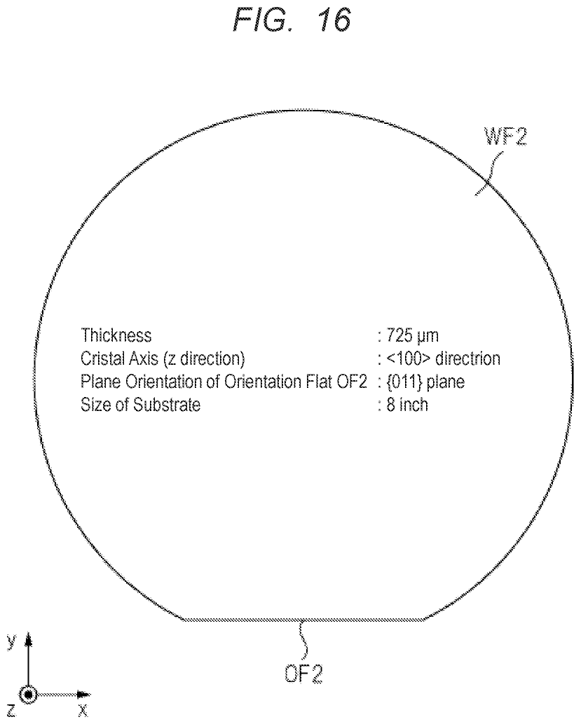

FIG. 16 is a drawing showing the semiconductor wafer WF2 called a 0-degree rotated substrate. In FIG. 16, a semiconductor wafer WF2 that is a 0-degree rotational substrate is composed of a stacked structure of a semiconductor substrate and an epitaxial layer, and has a thickness of, for example, 725 micrometers. Also, the crystal axis (z direction) is the <100> direction, and the plane orientation of the orientation flat OF2 is the {011} plane. Also, the size of the substrate is 8 inch. Such a semiconductor wafer WF2 is the 0-degree rotated substrate.

When a notch is formed on the semiconductor wafer WF2 instead of the orientation flat OF2, the 0-degree rotated substrate is a silicon substrate in which the crystal axis is in the <100> direction and the normal direction (notch symmetric axis direction) of the notch is in the <011> direction.

Here, each of the plurality of thin portions 110 respectively formed at the plurality of corner portions CNR includes an inclined portion having a <111> direction as a normal direction, and a flat portion having a <100> direction as a normal direction. When the 0-degree rotated substrate is used, the planar shape of each of the plurality of thin portions 110 is a quadrangular shape.

From the viewpoint of improving the reliability of the semiconductor chip CHP, it is preferable to adopt a configuration (see FIG. 3) in which the planar shape of the thin portion 100 is a triangular shape as compared with the configuration (see FIG. 14) of the present first modified example in which the planar shape of the thin portion 110 is a quadrangular shape. This is because, in a configuration in which the thin portion 100 has a triangular shape, the number of “corners” of the semiconductor chip CHP in which the stress is likely to concentrate can be made smaller (“two portions×four corners=eight portions”) than in a case where the semiconductor chip CHP has a rectangular shape (“three portions×four corners=twelve portions”).

In addition, from the viewpoint of reducing the ON-resistance of the semiconductor chip CHP, the embodiment using the 45-degree rotated substrate is more desirable than the present first modified example using the 0-degree rotated substrate. This is because, when the 45-degree rotated substrate is used, the channel plane through which the current of the vertical typed trench power MOSFET flows can be the {100} plane with the highest carrier mobility, while when the rotated substrate is used, the channel plane through which the current of the vertical typed trench power MOSFET flows is the {011} plane with the lower carrier mobility than the {100} plane.

### Second Modified Example

In the embodiment, an example in which a wet etching is used as a method of forming the thin portion has been described, but the present invention is not limited thereto, and as a method of forming the thin portion, dry etching or dicing including laser dicing may be used. However, in consideration of reducing damage to the semiconductor chip and securing the number of semiconductor chips acquired from the semiconductor wafer, it is desirable to use etching that is chemical processing rather than dicing that is machining as a method of forming a thin portion.

### Third Modified Example

Next, a third modified example will be described.

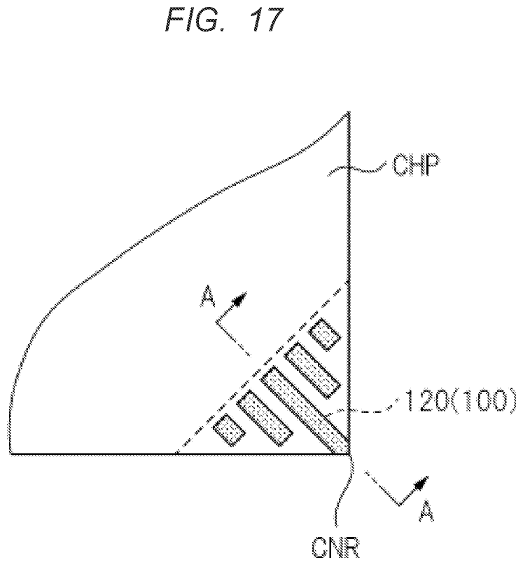

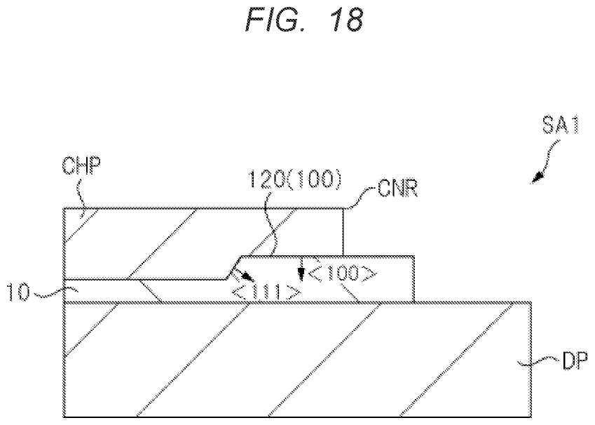

FIG. 17 is a drawing schematically showing a corner portion CNR of a semiconductor chip CHP, and FIG. 18 is a cross-sectional view of a semiconductor device SA1 corresponding to a cross section cut at A-A line in FIG. 17. As shown in FIGS. 17 and 18, a plurality of slit-groove portions 120 is formed at the corner portion CNR. As described above, the thin portion 100 formed at the corner portion CNR may be configured to have the plurality of slit-shaped groove portions 120.

Also in this case, since the thin portion 100 including the plurality of slit-groove portions 120 is formed only on the corner portion CNR, it is possible to secure the reliability that can withstand the temperature cycle test while achieving both the securing of the flexural strength of the semiconductor chip CHP and the suppression of the increase in the ON-resistance.

### Fourth Modified Example

Next, a fourth modified example will be described.

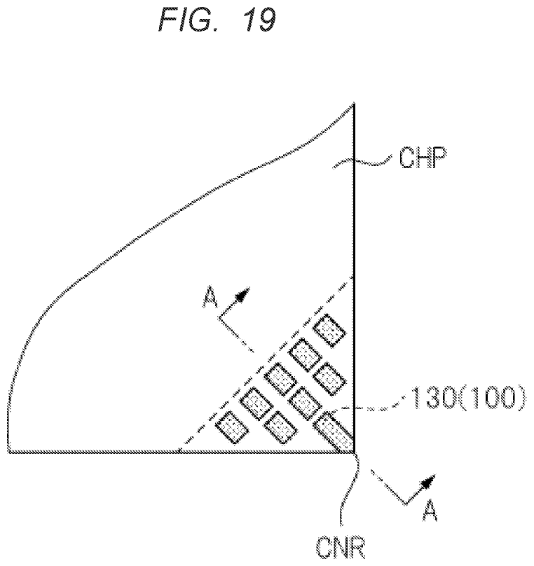

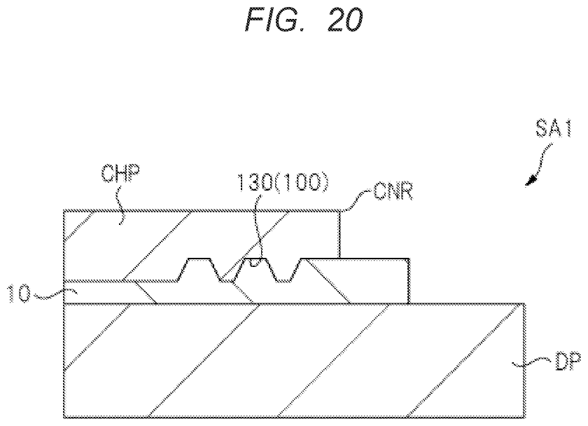

FIG. 19 is a drawing schematically showing a corner portion CNR of a semiconductor chip CHP, and FIG. 20 is a cross-sectional view of a semiconductor device SA1 corresponding to a cross section cut at A-A line in FIG. 19.

As shown in FIGS. 19 and 20, a plurality of lattice-groove portions 130 is formed in the corner portion CNR. As described above, the thin portion 100 formed at the corner portion CNR may be configured to have the plurality of lattice-groove portions 130.

Also in this case, since the thin portion 100 composed of the plurality of lattice-groove portions 130 is formed only in the corner portion CNR, it is possible to secure the reliability that can withstand the temperature cycle test while achieving both the securing of the flexural strength of the semiconductor chip CHP and the suppression of the increase in the ON-resistance.

The invention made by the present inventor has been described above in detail based on the embodiment, but the present invention is not limited to the embodiment described above, and it is needless to say that various modifications can be made without departing from the gist thereof.

What is claimed is:

1. A semiconductor device comprising:
a chip mounting portion; and
a semiconductor chip provided on the chip mounting portion via a conductive adhesive material,
wherein a planar shape of the semiconductor ship is a quadrangular shape,
wherein, in plan view, a plurality of thin portions is formed at a plurality of corner portions of the semiconductor chip, respectively,
wherein the plurality of thin portions respectively formed at the plurality of corner portions of the semiconductor chip is spaced apart from each other, and
wherein a thickness of each of the plurality of thin portions is smaller than a thickness of the semiconductor chip other than the plurality of the thin portions.

2. The semiconductor device according to claim 1,
wherein the semiconductor chip is a silicon chip,
wherein each of the plurality of thin portions has:
an inclined portion connected to a back surface of the semiconductor chip; and
a flat portion connected to the inclined portion,
wherein a normal direction of the inclined portion is <111> direction, and
wherein a normal direction of the flat portion is <100> direction.

3. The semiconductor device according to claim 1, wherein a planar shape of each of the plurality of thin portions is a triangular shape.

4. The semiconductor device according to claim 1,
wherein the semiconductor chip has:
a first corner portion provided at a one end portion of a first side of the semiconductor chip; and
a second corner portion provided at an other end portion of the first side of the semiconductor chip,
wherein a first thin portion of the plurality of thin portions is formed at the first corner portion,
wherein a second thin portion of the plurality of thin portions is formed at the second corner portion,
wherein a length of a side of the first thin portion is less than or equal to a quarter of a length of the first side, the side of the first thin portion being one of three sides each composing the first thin portion, and the side of the first thin portion overlapping the first side of the semiconductor chip, and
wherein a length of a side of the second thin portion is less than or equal to a quarter of the length of the first side, the side of the second thin portion being one of three sides each composing the second thin portion, and the side of the second thin portion overlapping the first side of the semiconductor chip.

5. The semiconductor device according to claim 1,
wherein the semiconductor chip has:
an active region in which a power transistor is formed;
a guard ring region surrounding the active region in plan view; and
a scribe region surrounding the guard ring region in plan view, and
wherein each of the plurality of thin portions is composed to have a region overlapping at least the scribe region and the guard ring region.

6. The semiconductor device according to claim 1,
wherein a vertical typed trench power MOSFET is formed in the semiconductor chip,
wherein the semiconductor chip includes a back surface electrode formed on a back surface of the semiconductor chip, and
wherein the back surface electrode is provided at each of the plurality of thin portions.

7. The semiconductor device according to claim 6, wherein a channel plane of the vertical typed trench power MOSFET is {100} plane.

8. The semiconductor device according to claim 1, wherein each of the plurality of thin portions is comprised of a plurality of slit-groove portions.

9. The semiconductor device according to claim 1, wherein each of the plurality of thin portions is comprised of a plurality of lattice-groove portions.

10. A method of manufacturing a semiconductor device, comprising steps of:
(a) forming a groove portions extending over a corner portion of each of a plurality of chip regions by partially removing a back surface of a semiconductor wafer, the semiconductor wafer having the plurality of chip regions and a scribe region located between the plurality of chip regions adjacent to each other; and
(b) obtaining a semiconductor chip by cutting the semiconductor wafer along the scribe region,
wherein a planar shape of the semiconductor ship obtained by the step of (b) is a quadrangular shape,
wherein, in plan view, a plurality of thin portions is formed at a plurality of corner portions of the semiconductor chip, respectively,
wherein one of the plurality of thin portions corresponds to a part of the groove portion formed in the step of (a),
wherein the plurality of thin portions respectively formed at the plurality of corner portions of the semiconductor chip is spaced apart from each other, and
wherein a thickness of each of the plurality of thin portions is smaller than a thickness of the semiconductor chip other than the plurality of the thin portions.

11. The method according to claim 10, wherein, in the step of (a), the groove portion having an inclined portion in which a normal direction thereof is <111> direction and a flat portion in which a normal direction thereof is <100> direction is formed by a wet etching process.

12. The method according to claim 11,
wherein the semiconductor wafer used in the step of (a) is a silicon substrate having:
a crystal axis of <100> direction; and
an orientation flat having a plane orientation of {100} plane, and
wherein a planar shape of each of the plurality of thin portions is a triangular shape.

13. The method according to claim 11,
wherein the semiconductor wafer used in the step of (a) is a silicon substrate having:
a crystal axis of <100> direction; and
an orientation flat having a plane orientation of {011} plane, and
wherein a planar shape of each of the plurality of thin portions is a quadrangular shape.

14. The method according to claim 11,
wherein the semiconductor wafer used in the step of (a) is a silicon substrate having:
a crystal axis of <100> direction; and
a notch having a normal direction of <100> direction, and
wherein a planar shape of each of the plurality of thin portions is a triangular shape.

15. The method according to claim 11,
wherein the semiconductor wafer used in the step of (a) is a silicon substrate having:
a crystal axis of <100> direction; and
a notch having a normal direction of <001> direction, and
wherein a planar shape of each of the plurality of thin portions is a quadrangular shape.
